(19) United States
(12) Patent Application Publication
(10) Pub. No.: US 2014/0174338 A1
(43) Pub. Date: Jun. 26, 2014

(54) METHODS TO BOND SILICA PARTS

(71) Applicant: SunEdison, Inc., St. Peters, MO (US)

(72) Inventors: Richard J. Phillips, St. Peters, MO (US); Shailendra B. Rathod, St. Louis, MO (US)

(21) Appl. No.: 14/134,861

(22) Filed: Dec. 19, 2013

Related U.S. Application Data
(60) Provisional application No. 61/740,943, filed on Dec. 21, 2012.

(51) Int. Cl. C30B 15/12; C03B 23/20; C30B 15/00

(52) U.S. Cl. CPC C30B 15/12; C30B 15/002; C03B 23/20
USPC 117/31; 117/213; 65/43; 65/32.2

(57) ABSTRACT

A method of bonding a first silica part to a second silica part includes coating contacting surfaces of the first and second silica parts with a solution having one of silica and silica precursors. The coated surfaces of the first silica part are placed adjacent to the coated surfaces of the second silica part to form an assembly, and the assembly is heated.

### CROSS REFERENCE

This application claims priority to U.S. Provisional Application No. 61/740,943 filed Dec. 21, 2012, the disclosure of which is hereby incorporated by reference in its entirety.

### FIELD

This disclosure generally relates to methods for bonding silica parts, and to silica crucibles used for growing single-crystal ingots.

### BACKGROUND

In the production of single silicon crystals grown by the Czochralski (CZ) method, polycrystalline silicon is first melted within a crucible, such as a quartz crucible, of a crystal pulling device to form a silicon melt. A seed crystal is lowered into the melt and slowly raised out of the melt to produce a silicon ingot. To produce a high quality single-crystal ingot using this method, the temperature and the stability of the surface of the melt immediately adjacent to the ingot must be maintained substantially constant. There is a need for a more effective system and method to limit temperature fluctuation and surface disruptions in the melt immediately adjacent to the ingot.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

A first aspect is a method of bonding a first silica part to a second silica part. The method includes providing the first and second silica parts; coating contacting surfaces of the first silica part and second silica part with a solution having at least one of silica and silica precursors; placing the coated surfaces of the first silica part adjacent to the coated surfaces of the second silica part to form an assembly; and heating the assembly.

Another aspect is a crucible for use in directional solidification of multicrystalline ingots. The crucible has a base, a sidewall extending around the base to form a vessel for the containment of material therein, and a weir attached to the base at a location inward from the sidewall to define an inner cavity and an outer cavity. The weir has at least one passage therethrough to allow material in the outer cavity to be moved to the inner cavity.

Still another aspect is a system for growing a single crystal ingot. The system includes a crucible, a heater, and a feed tube. The crucible has a base, a sidewall extending about the base to form a vessel for the containment of material therein, and a weir affixed to the base at a location inward from the sidewall to define an inner cavity and an outer cavity. The weir has at least one passage therethrough to allow material in the outer cavity to be moved to the inner cavity. The heater is located adjacent to the crucible for supplying heat to the crucible to maintain the silicon melt therein. The feed tube is connected with the crucible for supplying a feedstock material to the crucible.

Yet another aspect is a method for growing a single crystal ingot from a crucible having a base, a sidewall and a weir affixed to the base at a location inward from the sidewall to define an inner cavity and an outer cavity, the weir having at least one passage therethrough to allow material in the outer cavity to be moved to the inner cavity. The method includes placing a feedstock material into the crucible; melting the feedstock material to form a melt that passes through the passage from the outer cavity to the inner cavity; lowering a seed crystal into the melt; and pulling the seed crystal from the melt to pull an ingot from the seed crystal.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a partial cross sectional view of a crucible in accordance with one embodiment;

FIG. 2 is a schematic side view of a crystal growing system in accordance with another embodiment; and

FIG. 3 is a partial cross sectional view of a crucible in accordance with another embodiment.

Corresponding reference characters indicate corresponding parts throughout the several views of the drawings.

### DETAILED DESCRIPTION

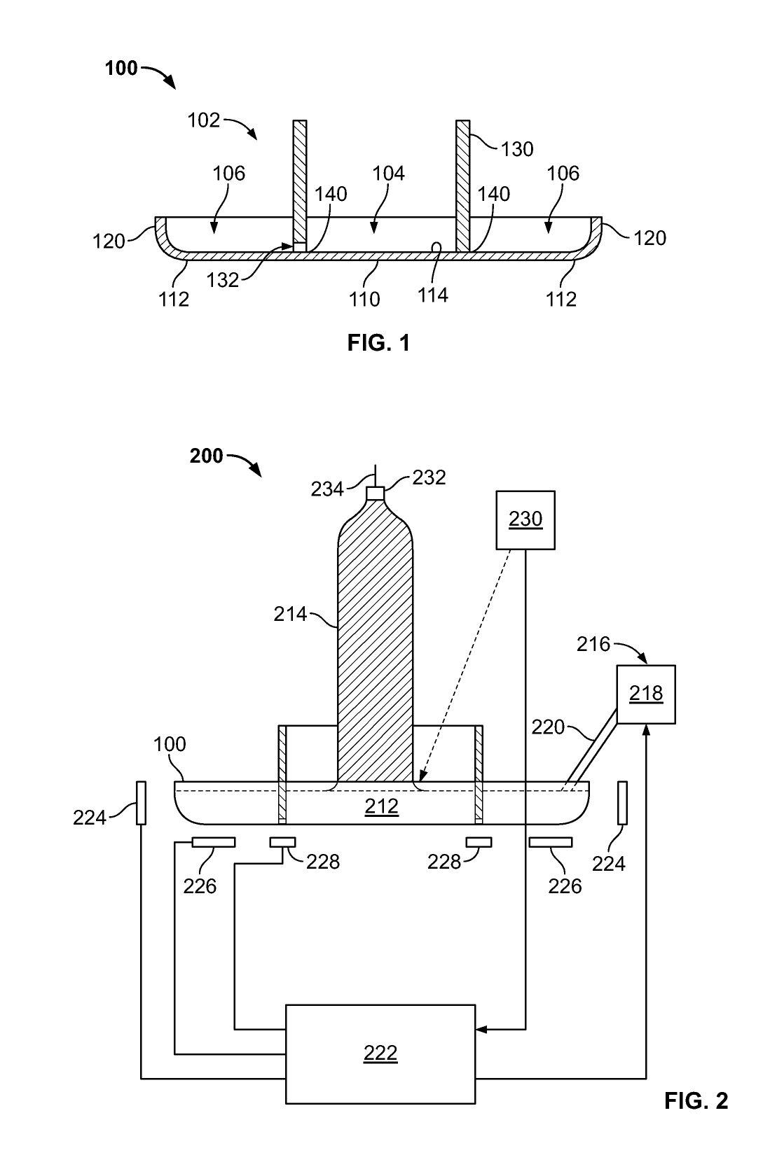

Referring to FIG. 1, a crucible for use in directional solidification of multicrystalline ingots is shown and indicated generally at 100. The crucible 100 has a base 110, a sidewall 120, and a weir 130. The sidewall 120 extends upward around a perimeter 112 of the base to form a concave hollow 102 in crucible 100 for the containment of material therein.

The weir 130 is affixed to the base 110 by a bonding agent 140. The affixed weir 130 extends upward from a top surface 114 of the base 110 at a location radially inward from the sidewall 120. The weir 130 separates the concave hollow 102 into an inner cavity 104 and an outer cavity 106. A passage 132 extends through the weir 130 to connect the inner cavity 104 and the outer cavity 106. Weir 130 may be a cylindrical body or any other suitable shape.

In a method of one embodiment for the production of a crucible having two or more parts made of fused silica, contacting surfaces of the parts are made to have a similar contour and to mate together. The contacting surfaces of each part are coated with solution containing silica or silica precursors (e.g., “slip”). The solution is prepared to develop a dispersed colloidal suspension and is typically brushed onto both sides of the contacting surfaces. The contacting surfaces are then pressed together and allowed to dry. The solution is typically an aqueous based system, so the solution is allowed to air dry.

After air drying, the joint is placed into a heating source capable of heating the parts to a specified temperature range, under controlled conditions to minimize devitrification, to bond the two surfaces together. The controlled conditions are such that the crystalline transformation of the silica, devitrification that yields cristobalite, is minimized. The controlled conditions include heating the coated parts in an inert atmosphere, such as argon—to a temperature in the range of about 1150° C. to about 1550° C. for between about 4 hours to almost 16 hours. The time is based on obtaining adequate viscous flow at the joint to effect bonding. The actual time will depend on the continuity of the joint after heat treatment to minimize or eliminate void space between the joint.

The solution may include slip casting agents, such as Cab-O-Sil, Thermosil, or other suitable slip cast agents. The solution may include a silica precursor, such as tetroalkoxysilane or other suitable silica precursor.

In another embodiment a crystal growing system is shown in FIG. 2 and indicated generally at 200. The crystal growing system 200 is used to produce a large crystal or ingot by the Czochralski method. The crystal growing system 200 includes the crucible 100 that contains a silicon melt 212 from which an ingot 214 is being pulled from the melt by a puller or puller system 234. During the crystal pulling process, a seed crystal 232 is lowered by a puller 234 into a melt 212 and then slowly raised from the silicon melt. As seed crystal 232 is slowly raised from melt 212, silicon atoms from the melt align themselves with and attach to the seed crystal to form an ingot 214. At this stage of the process, it is desirable to minimize defects within the ingot caused by misalignment of silicon atoms from the melt.

Feedstock material 216 may be placed into the outer cavity 106 of crucible 100, at a location radially outward from the weir, from feeder 218 through feed tube 220. The feedstock material 216 is at a much lower temperature than the surrounding melt 212 and absorbs heat from the melt as the feedstock material's temperature rises, and as the feedstock material itself melts. As feedstock material 216 absorbs energy from melt 212, the temperature of the surrounding melt falls immediately. During these fluctuations of the melt temperature, the ability of the silicon atoms to properly align themselves is hindered.

The amount of feedstock material 216 added is controlled by feeder 218, which is responsive to activation signals from a controller 222. Controller 222 is a computing device for controlling the feed rate of the feedstock material through the feed tube. The amount of cooling of the melt 212 is precisely determined and controlled by controller 222. Controller 222 either adds or does not add feedstock to adjust the temperature of the melt. As feedstock material 216 is added to melt 212, the surface of the melt may be disturbed. This disturbance also affects the ability of the melt silicon atoms to properly align with the silicon atoms of the seed crystal.

Heat is provided to crucible 100 by heaters 224, 226, and 228 located at various positions about the crucible. Heat from heaters 224, 226, and 228 melt or liquefies feedstock material 216 and then maintains melt 212 in a liquefied state. Heater 224 is generally cylindrical in shape and provides heat to the sides of the crucible 100, and heaters 226 and 228 provide heat to the bottom of the crucible. In some embodiments, heaters 226 and 228 are generally annular in shape.

Heaters 224, 226, and 228 are resistive heaters coupled to controller 222, which controllably applies electric current to the heaters to alter their temperature. A sensor 230, such as a pyrometer or like temperature sensor, provides a continuous measurement of the temperature of melt 212 at the crystal/melt interface of the growing single crystal ingot 214. Sensor 230 also may be directed to measure the temperature of the growing ingot. Sensor 230 is communicatively coupled with controller 222. Other temperature sensors may be added to measure and provide temperature feedback to the controller with respect to points that are critical to the growing ingot. While a single communication lead is shown for clarity, one or more temperature sensor(s) may be linked to the controller by multiple leads or a wireless connection, such as by an IR data link or other suitable connections.

The amount of current supplied to each of the heaters 224, 226, and 228 by controller 222 may be separately and independently chosen to optimize the thermal characteristics of melt 212. In some embodiments, one or more heaters may be disposed around the crucible to provide heat.

As discussed above, seed crystal 232 is attached to a portion of puller 234 located over melt 212. The puller 234 provides movement of seed crystal 232 in a direction perpendicular to the surface of melt 212 allowing the seed crystal to be lowered down toward or into the melt, and raised up or out of the melt. To produce an ingot 214, the melt 212 in an area adjacent to seed crystal 232/ingot 214 must be maintained at a substantially constant temperature and surface disruptions must be minimalized.

The weir 130 limits the surface disturbances and temperature fluctuations in the area immediately adjacent to seed crystal 232/ingot 214. Residual solid silicon pieces are also inhibited from passing through the passage to the inner cavity. In some embodiments, more than one weir may be used within the crucible, which will increase the residence time of dissolvable or meltable particles in the outer cavities. Similar bonding methods may be used on each weir to obtain a similar benefit of inhibiting residual solid silicon pieces from passing through and into the inner cavity.

The movement of the melt 212 is limited to the location of the passage 132. Placing passage 132 along a lower section of the weir 130 confines the movement of melt 212 to movement along the base 110 of the crucible 100. Thus, any movement of melt 212 into the inner melt portion is distal from or opposite the top of the melt (where the ingot 214 is being pulled). This confinement of the melt movement limits surface disruptions and temperature fluctuations along the top of the inner melt portion of the melt 212.

The passage 132 permits controlled movement of melt 212 between the outer cavity 106 and the inner cavity 104. Limiting the melt movement between the cavities 104, 106 allows the silicon material in the outer cavity 106 to heat to an approximately equivalent temperature of the melt in the inner cavity 104 as the silicon material passes through the passage 132.

With continued reference to FIG. 1, silicon is melted in the outer cavity, while solid silicon is fed continuously into the outer cavity 106. Thus feeding and melting are concurrent in cavity 106. The melt 212 passes from the outer cavity 106 to the inner cavity 104 through the passage 132. The ingot 214 is then grown from the melt 212 within the inner cavity 104.

The passage 132 may be disposed on the weir 130 at a location that is diametrically opposed to the feed tube 220 to increase the distance that feedstock material 216 must traverse before entering the inner cavity 104.

In a method of one embodiment for growing a single crystal ingot, the weir and the feedstock material are placed in the crucible. Heaters are placed adjacent to the crucible to provide heat for liquefying or melting the feedstock material forming a melt. The seed crystal is lowered into and then slowly raised out of the melt to grow the ingot from the seed crystal.

At the beginning of the process, feedstock material may be placed in both/either the inner cavity 104 and/or the outer cavity 106. During operation, the feedstock material may be placed in an area outside of the weir 130 for a continuous process of feeding and crystal growth. As the feedstock material outside of the weir 130 melts, the melt 212 is allowed to move from the outer cavity 106 into the inner cavity 104. The movement of the melt between the cavities 104, 106 is limited to passages through the outer leg and inner leg of the weir 130.

In some embodiments, the weir 130 does not include passages therethrough. In these embodiments, the weir 130 is bonded to the crucible at discrete locations along the length of the weir, defining unbounded portions. The unbounded portions form gaps, under the legs of the weir, between the weir and crucible. Movement of the melt from the outer cavity into the inner cavity is limited to movement through the gaps formed by the unbounded portions.

By limiting movement of the melt to along or near the base allows the temperature of the melt to increase as the melt passes from the outer cavity 106 into the inner cavity 104.

The melt entering the inner cavity 104 is substantially equivalent in temperature to the melt already in the inner cavity. Raising the temperature of the melt before reaching the inner cavity 104 reduces the temperature gradients within the inner cavity. The controller acts to maintain a substantially constant temperature within the inner cavity 104.

Further, limiting movement of the melt between the inner and outer cavities 104, 106 to along the base allows the surface of the inner cavity to remain relatively undisturbed. The weir 130 substantially prevents disturbances in the outer cavity 106 from disrupting the surface of the melt in the inner cavity 104 by substantially containing the energy waves produced by the disturbances. The disturbances are also limited by the location of the passage. The passage is along the bottom of the crucible, which allows movement of the melt into the inner cavity 104 without disrupting the surface stability of the inner cavity.

The temperature of the melt in the inner cavity 104 is measured at a location immediately adjacent the growing ingot by a sensor 230. The sensor is connected with the controller 222. The controller 222 adjusts the temperature of the melt by supplying more or less current to the heaters 224, 226, and 228 and by supplying more or less feedstock material to the melt. The controller 222 is also capable of simultaneously supplying feedstock material while the seed crystal is raised from the melt and growing the ingot.

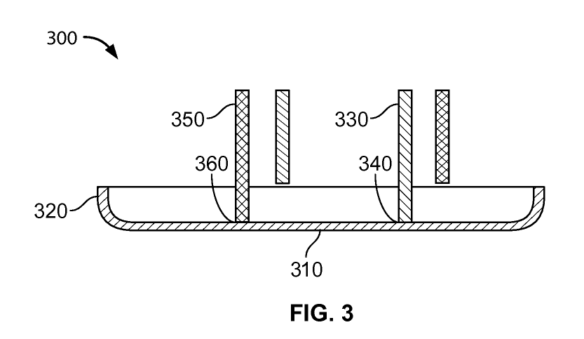

Referring to FIG. 3, another embodiment of a crucible for use in directional solidification of multicrystalline ingots is shown and indicated generally at 300. The crucible 300 has a base 310, a sidewall 320, a first weir 330, and a second weir 350. The first weir 330 is affixed to the base 310 by a bonding agent 340. The second weir 350 is also affixed to the base 310 by a bonding agent 360.

As disclosed herein, both the first weir 330 and second weir 350 are affixed to the base 310 with bonding agents 340 and 360, respectively. However, in some embodiments, only one of the first weir 310 and second weir 350 are affixed to the base 310. In other embodiments, the bonding agent 340 may be the same as bonding agent 360. In still other embodiments, the bonding agents 340 and 360 have different compositions.

Embodiments as described above enable increased yield and a better quality ingot, while decreasing the costs of the process. An example system with Cab-O-Sil was determined to perform more than four times better than a control or no slip system. This determination was made by a line/intercept method of intersection of voids at the interface.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the invention, it is intended that all matter contained in the above description and shown in the accompanying drawing[s] shall be interpreted as illustrative and not in a limiting sense.

What is claimed is:

1. A method of bonding a first silica part to a second silica part, the method comprising:
providing the first silica part;
providing the second silica part;
coating contacting surfaces of the first silica part and second silica part with a solution having at least one of silica and silica precursors;
placing the coated surfaces of the first silica part adjacent to the coated surfaces of the second silica part to form an assembly; and
heating the assembly.

2. The method of claim 1, wherein heating the assembly occurs in an inert atmosphere.

3. The method of claim 2, wherein the inert atmosphere is substantially argon.

4. The method of claim 1, wherein heating the assembly is performed in a range of about 1150° C. to about 1550° C.

5. The method of claim 1, wherein heating the assembly is performed for between about 4 hours and about 16 hours.

6. The method of claim 1, wherein the solution includes a silica precursor, the silica precursor is tetroalkoxysilane.

7. A crucible for use in directional solidification of multicrystalline ingots, the crucible comprising:
a base;
a sidewall extending around the base to form a vessel for the containment of material therein; and
a weir attached to the base at a location inward from the sidewall to define an inner cavity and an outer cavity, the weir having at least one passage therethrough to allow material in the outer cavity to be moved into the inner cavity.

8. The crucible of claim 7, wherein the weir is attached to the base with a bonding agent selected from one of a silica and a silica precursor.

9. The crucible of claim 7, wherein the bonding agent is selected from one of Cab-O-Sil, Thermosil, and tetroalkoxysilane.

10. The crucible of claim 7, further comprising a second weir located inward from the sidewall.

11. A system for growing a single crystal ingot, the system comprising:
a crucible having:
a base;
a sidewall extending about the base to form a vessel for the containment of material therein; and
a weir affixed to the base at a location inward from the sidewall to define an inner cavity and an outer cavity, the weir has at least one passage therethrough to allow material in the outer cavity to be moved into the inner cavity;
a heater located adjacent to the crucible for supplying heat to the crucible to maintain the melt material contained therein; and
a feed tube connected with the crucible for supplying a feedstock material to the crucible.

12. The system of claim 10, further comprising a computing device for controlling the feed rate of the feedstock material through the feed tube.

13. The system of claim 10, further comprising a puller system for lowering and raising a seed crystal into and out of the silicon melt.

14. The system of claim 10, further comprising a controller for adjusting the amount of heat provided by the heater to the crucible.

15. The system of claim 10, wherein the crucible includes a second weir located inward from the sidewall.

16. A method for growing a single crystal ingot from a crucible having a base and a sidewall and a weir affixed to the base at a location inward from the sidewall to define an inner cavity and an outer cavity, the weir having at least one passage therethrough to allow material in the outer cavity to be moved into the inner cavity, the method comprising:
placing a feedstock material into the crucible;
melting the feedstock material to form a melt that passes through the passage from the outer cavity to the inner cavity;
lowering a seed crystal into the melt; and
pulling the seed crystal from the melt to pull an ingot from the seed crystal.

17. The method of claim 14, wherein the feedstock material is placed into the crucible at a location radially outward from the weir.

18. The method of claim 14, further comprising measuring a temperature of the melt at a location immediately adjacent the growing ingot.

19. The method of claim 14, wherein the ingot is pulled simultaneously with placing the feedstock material into the crucible.
